(19) United States
(12) Patent Application Publication
(10) Pub. No.: US 2008/0053688 A1
(43) Pub. Date: Mar. 6, 2008

(54) Printed circuit board and method of manufacturing the same

(75) Inventors: Jun Heyoung Park, Gyunggi-do (KR); Taehoon Kim, Gyunggi-do (KR); Dong Sun Kim, Gyunggi-do (KR); Sam Jin Her, Gyunggi-do (KR); Seung Chul Kim, Chungcheongbuk-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/896,299

(22) Filed: Aug. 30, 2007

(30) Foreign Application Priority Data
Sep. 1, 2006 (KR) 10-2006-0084184
Jul. 25, 2007 (KR) 10-2007-0074625

(51) Int. Cl. H05K 1/00; H05K 3/10

(52) U.S. Cl. 174/258; 174/250; 29/846

(57) ABSTRACT

Disclosed herein are a thin printed circuit board, in which a pair of high-functional resin substrates having a permittivity ranging from 1.5 to 4.0, on one surface of each of which a circuit pattern is formed through ion-beam surface treatment, vapor deposition and electroplating, are layered with an insulating layer interposed therebetween, and a method of manufacturing the printed circuit board. The circuit patterns are positioned inside the substrates. Thereafter, external layers are formed through ion-beam surface treatment, vapor deposition and electroplating. According to the present invention, the adhesiveness between each of the substrates and a metal layer may be improved through the ion-beam surface treatment/vapor deposition. Furthermore, since the pair of resin substrates are layered with the insulating layer interposed therebetween, the circuit patterns may be disposed inside the pair of resin substrates, so that the total thickness of the substrate may be reduced, thereby realizing highly reliable fine circuits.

### CROSS REFERENCE TO RELATED APPLICATIONS

This application claims the benefit of Korean Patent Application No. 10-2006-0084184, filed on Sep. 1, 2006, entitled “Printed Circuit Board and Manufacturing Method Thereof,” and Korean Patent Application No. 10-2007-0074625, filed on Jul. 25, 2007, entitled “Printed Circuit Board and Manufacturing Method Thereof,” which are hereby incorporated by reference in their entirety in this application.

### BACKGROUND OF THE INVENTION

1. Field of the Invention

The present invention relates generally to a printed circuit board and a method of manufacturing the printed circuit board. More particularly, the present invention relates to a printed circuit board and a method of manufacturing the printed circuit board, in which a pair of high-functional resin substrates, on one surface of each of which a circuit pattern is formed through ion-beam surface treatment, vapor deposition and electroplating, are layered with an insulating layer interposed therebetween, thereby realizing highly reliable fine circuits.

2. Description of the Related Art

Recently, as electronic devices have become small, highly integrated and multifunctional, technology for package substrates has been rapidly developed so as to realize lightweight, thin, short, small, and highly integrated fine circuit patterns. In particular, such lightweight, thin, short, small, and highly integrated fine circuit patterns are required for the Chip Scale Package (CSP) product group, in which semiconductor chips are disposed on the substrates of Ball Grid Array (BGA) packages. However, it is difficult to realize wiring having 60 or fewer pitches using a method of forming circuits on a Copper Clad Laminate (CCL), which is a base substrate, using a typical etching process (for example, a subtractive method). Further, it is difficult to form wiring having 50 or fewer pitches using a method of reducing the thickness of the copper foil of a CCL, or forming circuits using a thin copper foil having a thickness of 3 μm or less. In addition, in order to deal with an increase in the number of pins formed on the substrate of a BGA package and heat generated at the time of bonding chips, there is a demand for the development of an insulating material having excellent insulation characteristics and stability at high temperature, which can replace an existing Bismaleimide Triazine (BT) insulating material. Since PolyImide (PI), Liquid Crystal Polymer (LCP), and PolyTetraFluoroEthylene (PTFE) have excellent insulation characteristics and high Tg, there is a strong possibility that they will be selected as insulating materials in the future. However, since these insulating materials have weak adhesiveness to the copper foil when layers are formed, it is difficult to use them as insulating material.

With regard to this, a process of manufacturing a printed circuit board according to an embodiment of the prior art is shown in FIGS. 5A to 5K. A description thereof will be given below with reference to these drawings.

First, a through hole 13 is formed in an epoxy resin substrate 11, interposed between copper layers 12, through general etching and drilling processes (refer to FIGS. 5A and 5B). Thereafter, a desmearing process is performed on the surfaces of the substrate in which the through hole 13 is formed, electroless copper plating layers 14 are formed through electroless panel plating, and electrolytic copper plating layers 15 are formed through electrolytic panel plating (refer to FIG. 5C). The through hole 13 is filled with a conductive paste 16 (refer to FIG. 5D), dry films 17 are applied over the through hole 13 and predetermined portions where circuit patterns will be formed (refer to FIG. 5E), and the process of forming a core circuit layer is completed (refer to FIG. 5F) in such a way that unnecessary portions of the copper layers are removed through general exposure, development and etching processes and the dry films 17 are removed.

Next, before a process of forming an external layer is performed, the surfaces of the substrate are treated through, for example, a CZ process, which is a general surface treatment process known in a related field, single-sided CCLs, on one surface of each of which a copper layer 19 is layered, are layered on the epoxy resin substrates 18 (refer to FIG. 5G), and blind via holes 20 are formed through general etching and drilling processes (refer to FIG. 5H). Thereafter, a desmearing process is performed on the surfaces of the substrates in which the blind via holes 20 are formed, copper plating layers 21 are formed through the electroless and electrolytic panel plating (refer to FIG. 5I), dry films 22 are applied over the blind via holes 20 and portions where the circuit patterns will be formed (refer to FIG. 5J), and the process of forming external layer circuits is completed (refer to FIG. 5K) in such a way that unnecessary portions of the copper layers are removed through general exposure, development and etching processes and the dry films 22 are removed. As described above, in order to fabricate thin plate products having fine patterns, a method of forming circuits by burying patterns in insulating material layers or by using copper foils having a thickness of 3 μm or less has been used in the prior art. In addition, a method of forming fine patterns on BT insulating material by using a semiadditive method or by performing copper plating has been attempted. However, there is a problem in that the adhesiveness between a copper plating layer and an insulating material layer is still weak.

### SUMMARY OF THE INVENTION

Accordingly, in order to overcome the above problems occurring in the prior art, extensive research has been carried out. The result of this research is a thin printed circuit board, in which a pair of high-functional resin substrates having a permittivity ranging from 1.5 to 4.0, on one surface of each of which a circuit pattern is formed through ion-beam surface treatment, vapor deposition and electroplating, are layered with the circuit patterns interposed inside the substrates, and external layers are formed thereon, thereby realizing high-functional and highly reliable fine circuits. The present invention has been completed based on this scheme.

Accordingly, the present invention is intended to provide a high-functional and high-density printed circuit board and a method of manufacturing the printed circuit board.

Furthermore, the present invention is intended to provide a thin printed circuit board having uniform impedance characteristics and a method of manufacturing the thin printed circuit board.

Moreover, the present invention is intended to provide a printed circuit board, in which fine circuits can be realized, substrates thereof are hardly deformed, and the layer-to-layer registration thereof is excellent, and a method of manufacturing the printed circuit board.

In an embodiment, the present invention provides a printed circuit board, including a first resin substrate having a first circuit pattern on one surface thereof, a second resin substrate having a second circuit pattern on one surface thereof; an insulating layer interposed between the first resin substrate and the second resin substrate, with the first circuit pattern and the second circuit pattern being disposed inside the first and second resin substrates; one or more blind via holes and a through hole formed in the first resin substrate, the second resin substrate, and the insulating layer; a third circuit pattern formed on the remaining surface of the first resin substrate, and a fourth circuit pattern formed on the remaining surface of the second resin substrate; and a metal layer formed on the wall of the through hole; wherein the first and second resin substrates have a permittivity ranging from 1.5 to 4.0; and wherein the first to fourth circuit patterns are each formed of a metal seed layer formed through ion-beam surface treatment and vapor deposition, and a metal electrolytic plating layer formed through electroplating.

In the above printed circuit, the resins of the first and second resin substrates are selected from the group consisting of PolyTetraFluoroEthylene (PTFE), PolyImide (PI), Liquid Crystal Polymer (LCP), and combinations thereof. In an embodiment, the insulating layer is made of material selected from the group consisting of thermoplastic resin, thermosetting resin, reinforced thermoplastic resin, reinforced thermosetting resin, and combinations thereof.

In an embodiment, the present invention provides a method of manufacturing a printed circuit board, including providing a pair of resin substrates having a permittivity ranging from 1.5 to 4.0; processing one surface of each of the resin substrates using an ion-beam; forming a metal seed layer on each of the pair of resin substrates, the surfaces of which are processed using a vapor deposition process; forming a metal pattern plating layer on the metal seed layer using an electroplating process; removing the metal seed layer disposed on portions where the metal pattern plating layer is not formed, and forming a circuit pattern; disposing an insulating layer between the pair of resin substrates, on one surface of each of which the circuit pattern is formed, with the circuit patterns being disposed inside the pair of resin substrates; forming one or more blind via holes and a through hole in the layered resin substrates; and processing the surfaces of the resin substrates, in which the blind via holes and the through hole are formed, using an ion beam, and repeating the operations ranging from the forming of the metal seed layer to the removing of the metal seed layer.

In an embodiment, the resin substrates are C-stage films.

In an embodiment, the processing of the surfaces of the resin substrates using an ion beam is performed in the state in which an inactive gas selected from the group consisting of Ar, O₂, N₂, Xe, CF₄, H₂, Ne, Kr and combinations thereof exists.

In another embodiment, the present invention provides a printed circuit board, including a first resin substrate including a first circuit pattern having a first land on one surface thereof; a second resin substrate including a second circuit pattern having a second land on one surface thereof; an insulating layer interposed between the first resin substrate and the second resin substrate, with the first circuit pattern and the second circuit pattern being disposed inside the first and second resin substrates; one or more bumps formed to electrically connect the first land and the second land; one or more blind via holes formed in the first resin substrate and the second resin substrate; and a third circuit pattern formed on the remaining surface of the first resin substrate, and a fourth circuit pattern formed on the remaining surface of the second resin substrate; wherein the first and second resin substrates have a permittivity ranging from 1.5 to 4.0; and wherein the first to fourth circuit patterns are each formed of a metal seed layer formed through ion-beam surface treatment and vapor deposition, and a metal electrolytic plating layer formed through electroplating.

In the second preferred embodiment, the present invention provides a method of manufacturing a printed circuit board, including providing a resin substrate having a permittivity ranging from 1.5 to 4.0; processing one surface of the resin substrate using an ion-beam; forming a metal seed layer on the resin substrate, the surface of which is processed using a vapor deposition process; forming a metal pattern plating layer on the metal seed layer using an electroplating process; removing the metal seed layer disposed on portions on which the metal pattern plating layer is not formed, and forming a circuit pattern including a land; forming one or more cone-shaped bumps on the land; layering an insulating layer on the resin substrate, on which the cone-shaped bumps are formed, with a portion of each of the cone-shaped bumps passing through the insulating layer, so that the portions of the bumps are exposed; preparing a resin substrate including a circuit pattern having a land by repeating the operations ranging from the providing of the resin substrate to the removing of the metal seed layer; layering the resin substrate, obtained in the preparing of the resin substrate, on the insulating layer, obtained in the layering of the insulating layer through which the part of the cone-shaped bumps are exposed, with the bumps being interposed between the lands opposite each other; forming one or more blind via holes in the layered resin substrates obtained in the layering of the resin substrate; and processing surfaces of the resin substrates, through which the blind via holes are formed, using an ion beam, and repeating the operations ranging from the forming of the metal seed layer to the removing of the metal seed layer.

### BRIEF DESCRIPTION OF THE DRAWINGS

The above and other objects, features and advantages of the present invention will be more clearly understood from the following detailed description taken in conjunction with the accompanying drawings, in which:

FIGS. 1A to 1J are diagrams schematically showing the flow of a process of manufacturing a printed circuit board according to a first preferred embodiment of the present invention;

FIGS. 2A to 2I are diagrams schematically showing the flow of a process of manufacturing a printed circuit board according to a second preferred embodiment of the present invention;

FIG. 3 is an optical microscope photo (×500) showing the cross-sectional structure of the printed circuit board manufactured according to the first preferred embodiment of the present invention;

FIG. 4 is an optical microscope photo (×500) showing the cross-sectional structure of the printed circuit board manufactured according to another preferred embodiment of the present invention; and

FIGS. 5A to 5K are diagrams schematically showing the flow of a process of manufacturing a printed circuit board according to an embodiment of the prior art.

### DESCRIPTION OF THE PREFERRED EMBODIMENTS

The present invention will be described in detail with reference to the accompanying drawings below.

The present invention provides a high-functional thin printed circuit board and a method of manufacturing the printed circuit board, in which a pair of substrates, in each of which a copper layer is formed on a high-functional resin, such as PolyImide (PI), Liquid Crystal Polymer (LCP), or PolyTetraFluoroEthylene (PTFE), having a permittivity ranging from about 1.5 to about 4.0, through ion-beam surface treatment and vapor deposition, and a circuit pattern is formed in the copper layer, are layered with an insulating layer interposed therebetween, one or more through holes and one or more via holes are formed in the remaining surfaces of the respective layered substrates, and external circuit patterns are formed.

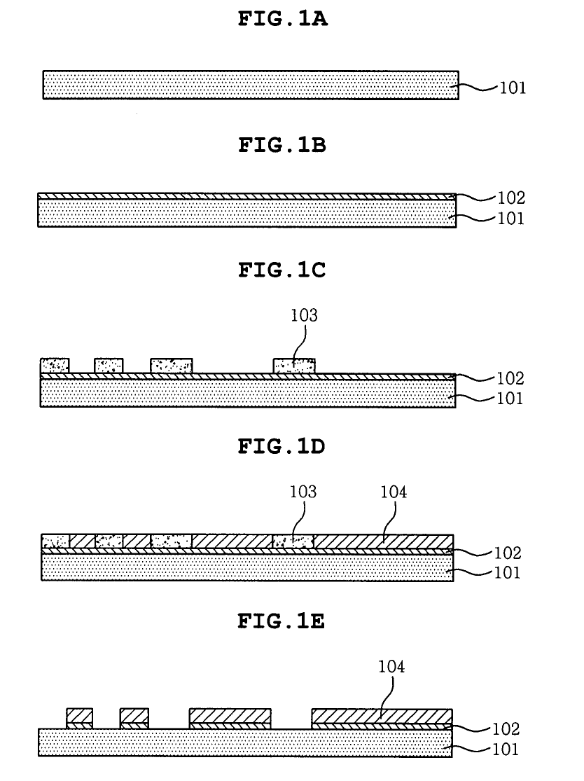

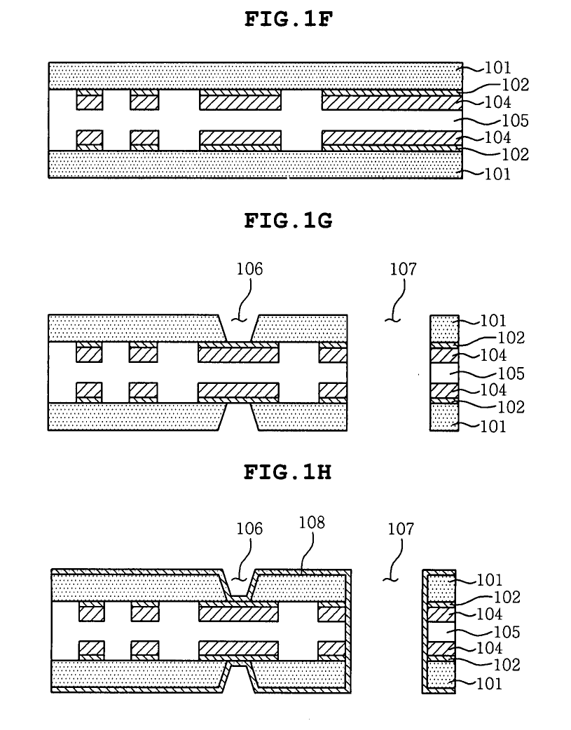

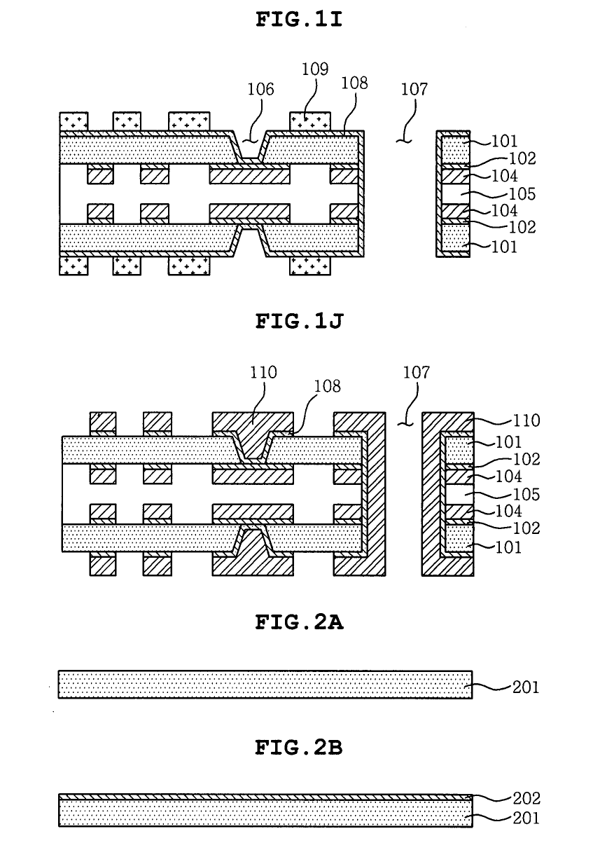

FIGS. 1A to 1J schematically show the flow of a process of manufacturing a printed circuit board according to a first embodiment of the present invention.

Although the process of manufacturing a printed circuit board according to the present invention will be described in conjunction with an embodiment in detail with reference to FIGS. 1A to 1J below, the scope of the present invention is not limited thereto.

First, a resin substrate 101 for a printed circuit board, made of a resin having a permittivity ranging from about 1.5 to 4.0, is prepared (refer to FIG. 1A). Although an epoxy resin, such as Bismaleimide Triazine (BT), has generally been used, a high-functional resin substrate made of, for example, PolyImide (PI), Liquid Crystal Polymer (LCP), PolyTetraFluoroEthylene (PTFE), or a combination thereof is used in the present invention. In an embodiment, the resin may be a C-stage, completely hardened film-type insulating material, which is used as an interlayer insulating material. Thereafter, one surface of the substrate 101 is treated using an ion beam, and a metal seed layer 102 having a desired thickness is formed on the ion-beam treated substrate 101 through a vapor deposition process (refer to FIG. 1B).

Here, although any conductive metal applicable to the forming of a circuit may be used as the metal without special limitation, copper is typically used in view of economic efficiency.

In an embodiment, the above-described ion-beam surface treatment process may be performed at an amount of ion implantation ranging from 1E15 to 1E19 (ions/cm²) and an acceleration voltage ranging from 0.5 to 20 keV in the presence of an inactive gas selected from the group consisting of Ar, O₂, N₂, Xe, CF₄, H₂, Ne, Kr and combinations thereof. However, the conditions of the process are not limited to the above-described conditions, but it will be apparent to those skilled in the art that the actual conditions of the process may be appropriately adjusted depending on the material of the substrate.

The adhesiveness of the resin substrate to the metal seed layer, which will be formed in the following process, can be increased through the above-described dry ion-beam surface treatment process. That is, a fine circuit can be realized by exciting the surface of the high molecular substance and forming unstable linkers through the application of inactive/reactive ions having energy onto the surface of a high molecular substance, which is the material of the resin substrate, and causing a chemical reaction and changing the characteristic of the surface from a hydrophilic property to a hydrophobic property through the supply of an active gas (for example, oxide), thereby increasing boundary surface adhesiveness.

Meanwhile, although a sputtering process, a thermal evaporation process, an e-beam process, or a combination thereof may be used as the vapor deposition process, the vapor deposition process is not limited thereto, but one of the processes known in the related field may be used without special limitation.

The thickness of the metal seed layer formed through the above-described process may be appropriately adjusted within a range of 0.02 to 0.5 μm depending on the purpose of the application.

Thereafter, as known in the related field, a dry film 103, which will act as a plating resist, is applied onto predetermined portions, other than portions in which pattern plating will be performed, using a semiadditive method (refer to FIG. 1C), and a metal pattern plating layer 104 is formed through electrolytic metal pattern plating (refer to FIG. 1D).

The dry film 103 is removed, and the metal seed layer 102, provided on portions in which the metal pattern plating layer 104 is not formed, is removed through a general flash etching process, thereby forming an internal circuit layer (refer to FIG. 1E).

The circuit patterns of a pair of internal circuit layers, constructed as described above, are positioned inside the internal circuit layers, and an adhesive insulating layer 105, such as prepreg, is interposed between the internal circuit layers (refer to FIG. 1F). The adhesive insulating layer 105 is used to realize formability and to correct the bending of the substrates occurring when the circuit layers are layered. Any material for the adhesive insulating layer 105 known in the related field may be used without special limitations. For example, the material of the adhesive insulating layer 105 may be appropriately selected from among a thermoplastic resin, a thermosetting resin, a reinforced thermoplastic resin, a reinforced thermosetting resin, and combinations thereof, and is then used. Thereafter, blind via holes 106 and a through hole 107 are formed through the layered substrates so as to connect internal layers with external layers (refer to FIG. 1G).

Next, the surfaces of the substrates, in which the blind via holes 106 and the through hole 107 are formed, are treated using an ion-beam based on a method identical to the method of forming the internal layers, and metal seed layers 108 having a desired thickness are formed on the ion-beam treated substrates through vapor deposition (refer to FIG. 1H).

Thereafter, as known in the related field, dry films 109, which will act as plating resists, are applied onto predetermined portions, other than portions on which the pattern plating will be performed, using a semiadditive method (refer to FIG. 1I), and external circuit layers are formed (refer to FIG. 1J) in such a way that electrolytic metal pattern plating is performed, the dry films 109 are removed, and the metal seed layers 108, formed on portions on which pattern plating layers 110 are not formed, are removed using a general flash etching process. Any process, known in the related field, may be performed depending on the purpose of the application of the printed circuit board without special limitations. For example, selectively, a process of laying external layers using a semiadditive method may be repeatedly performed on the substrates, manufactured as described above, several times, or predetermined subsequent processes may be performed on the substrates.

Further, for example, in the case where the substrate is used as the outermost layer of a Flip Chip Ball Grid Array (FCBGA) substrate, a solder resist is applied on the external circuit layer, a solder resist opening portion is formed through a general solder resist opening process, and one or more bumps may be formed through general electroless nickel/gold plating, as known in the related field.

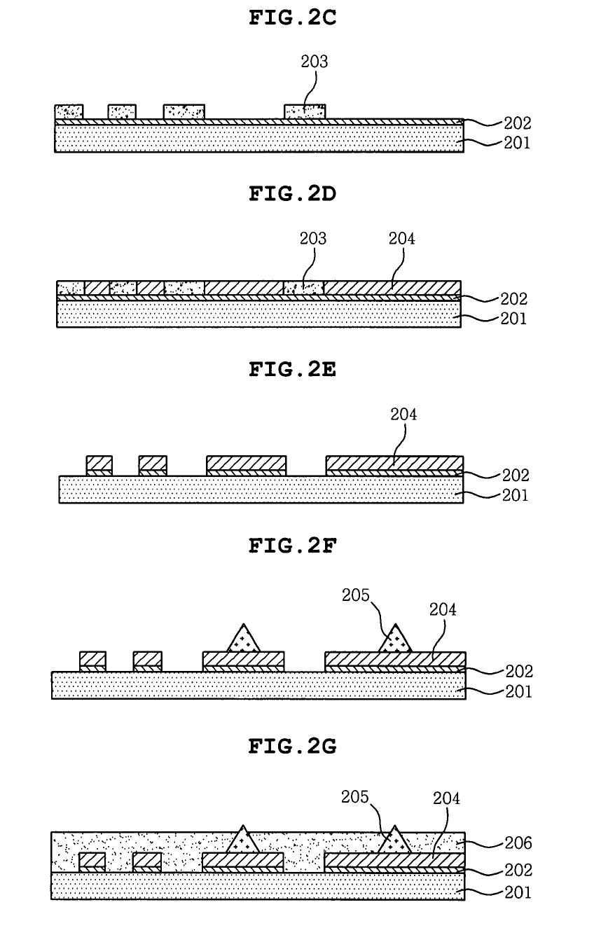

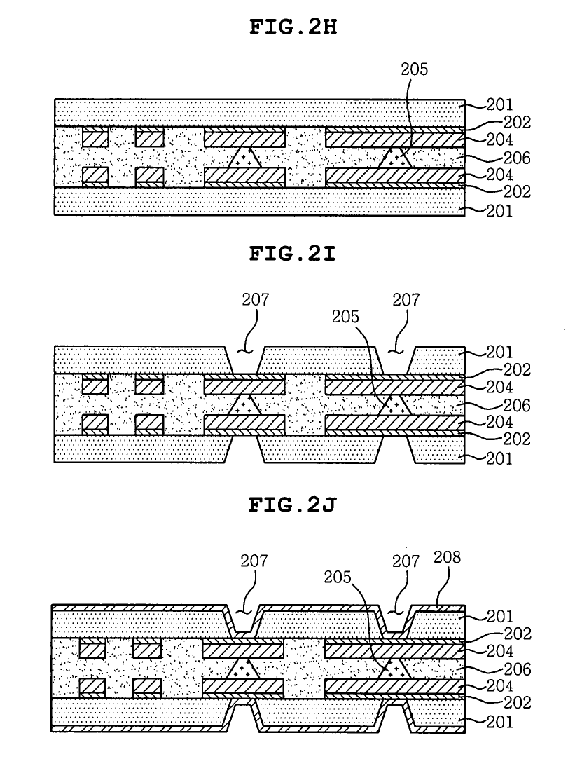

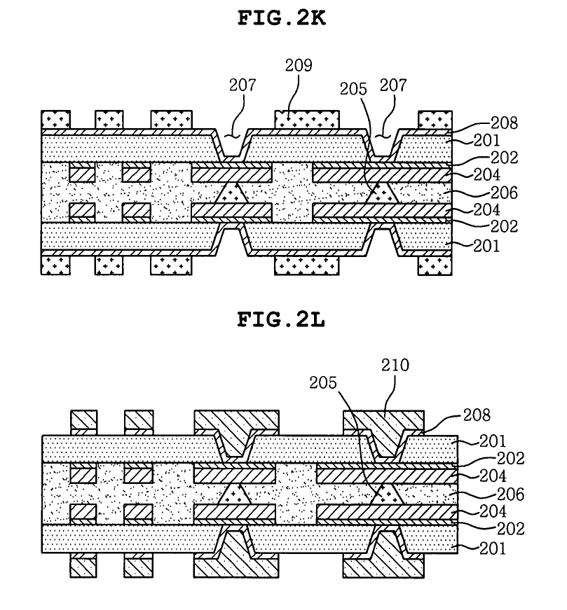

FIGS. 2A to 2I schematically show the flow of a process of manufacturing a printed circuit board according to a second preferred embodiment of the present invention.

Although the process of manufacturing a printed circuit board according to the present invention will be described in conjunction with an embodiment in detail with reference to FIGS. 2A to 2I below, the scope of the present invention is not limited thereto.

First, a resin substrate 201 for a printed circuit board, made of a resin having a permittivity ranging from about 1.5 to about 4.0, is prepared (refer to FIG. 2A). The resin substrate, described in conjunction with FIG. 1A, may be used as the resin substrate 201.

Thereafter, one surface of the substrate 201 is treated using an ion beam, and a metal seed layer 202 having a desired thickness is formed on the ion-beam treated substrate 201 using a vapor deposition process (refer to FIG. 2B).

Here, although any conductive metal applicable to the forming of a circuit may be used as the metal without special limitations, copper is typically used in view of economic efficiency.

The ion-beam surface treatment process and the vapor deposition process may be performed as described in detail in conjunction with FIG. 1B. The thickness of the metal seed layer that is formed using the ion-beam surface treatment process and the vapor deposition process may be appropriately adjusted within the range of 0.02 to 0.5 μm depending on the purpose of the application thereof.

Thereafter, as known in the related field, a dry film 203, which will act as a plating resist, is applied onto predetermined portions, other than portions on which pattern plating will be performed, using a semiadditive method (refer to FIG. 2C), and a metal pattern plating layer 104 is formed through electrolytic pattern plating (refer to FIG. 2D).

An internal circuit layer including a land is formed (refer to FIG. 2E) in such a way that the dry film 203 is removed, and the metal seed layer 202, provided on portions on which the pattern plating layer 204 is not formed, is removed through the general flash etching process. Thereafter, bumps 205 having a cone shape are formed on the land 204 using, in an embodiment, a conductive paste (refer to FIG. 2F).

Any conductive paste known in the related field may be used without special limitation. A paste resin composition generally includes electroconductive metal powder or carbon powder, binder resin, a hardening agent, a catalytic agent, and additives. When necessary, a diluent or a filling material may be added thereto. For example, the paste resin composition may be a silver paste resin composition, a copper paste resin composition, a gold/silver paste resin composition, or a silver/carbon paste resin composition. Further, any generally known powder may be used as the electroconductive powder of the electroconductive paste resin composition without special limitation. In particular, the powder of a single metal, such as gold, silver, copper, palladium, nickel, or cobalt, or the powder of a known alloy, solder, or stainless steel may be used as the electroconductive powder, and one, two, or more kinds of carbon may be used as the electroconductive powder. Any generally known size or shape of electroconductive powder may be used without special imitation. In particular, the shape of the electroconductive powder may be selected from among a spherical shape, an indeterminate shape, a needle shape, a thin film shape, a special shape, and combinations thereof. In the case of the electroconductive powder having a spherical shape or an indeterminate shape, the diameter of the particles of the electroconductive powder may range from 0.1 to 10 μm so that the particles are dispersed throughout the paste without sedimentation. In addition, nanoparticles of known metal or carbon may be used, in which case the nanoparticles are combined with the electroconductive particle and are then used.

Thereafter, a B-stage insulating layer 206, such as prepreg, is layered on the resin substrate, on which the cone-shaped bumps 205 are formed, in such a way that parts of the cone-shaped bumps 205 pass through the insulating layer 206, and thus the parts of the bump 205 are exposed (refer to FIG. 2G).

Meanwhile, as described in conjunction with FIGS. 2A to 2E above, a separate resin substrate, on which a circuit pattern including a land is formed, is prepared.

The prepared resin substrate is layered on the insulating layer 206, which is obtained as in FIG. 2G and through which the parts of the cone-shaped bump 205 are exposed, so that the lands 202+204 are opposite each other, with the bumps 205 interposed therebetween (refer to FIG. 2H).

Thereafter, blind via holes 207 are formed in the layered substrates to connect internal layers and external layers (refer to FIG. 2I).

Next, the surfaces of the substrates, through which the blind via holes 207 are formed, are treated using an ion beam by a method identical to the method of forming the internal layers, and metal seed layers 208 having a desired thickness are respectively formed on the ion-beam treated substrates 201 through the vapor deposition process (refer to FIG. 2J). Thereafter, as is known in the related field, dry films 209, which will act as plating resists, are applied onto predetermined portions, other than portions on which pattern plating will be performed, using a semiadditive method (refer to FIG. 2K), and external circuit layers are formed (refer to FIG. 2I) in such a way that electrolytic metal pattern plating is performed, the dry films 109 are removed, and the metal seed layers 208, disposed on portions on which a pattern plating layer 210 is not formed, are removed through a general flash etching process.

Any process, known in the related field, may be performed according to the purpose of the application of the printed circuit board without special limitation. For example, selectively, a process of laying the external layers using a semiadditive method may be repeatedly performed on the substrates manufactured as described above several times, or predetermined subsequent processes may be performed on the substrates.

Further, for example, in the case where the substrate is used as the outermost layer of a Flip Chip Ball Grid Array (FCBGA) substrate, a solder resist is applied on the external circuit layer, a solder resist opening portion is formed through a general solder resist opening process, and one or more bumps may be formed through general electroless nickel/gold plating, as known in the related field.

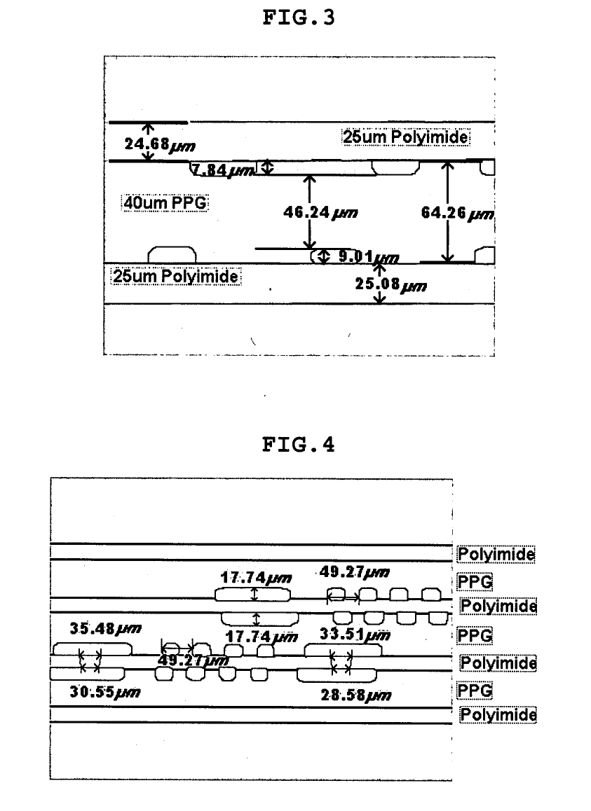

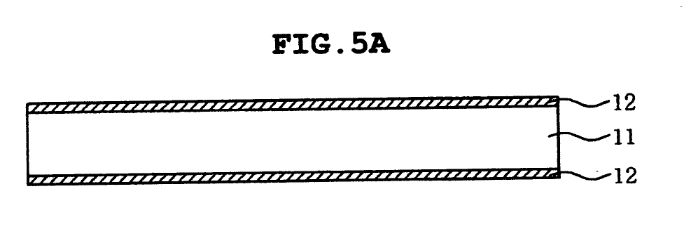

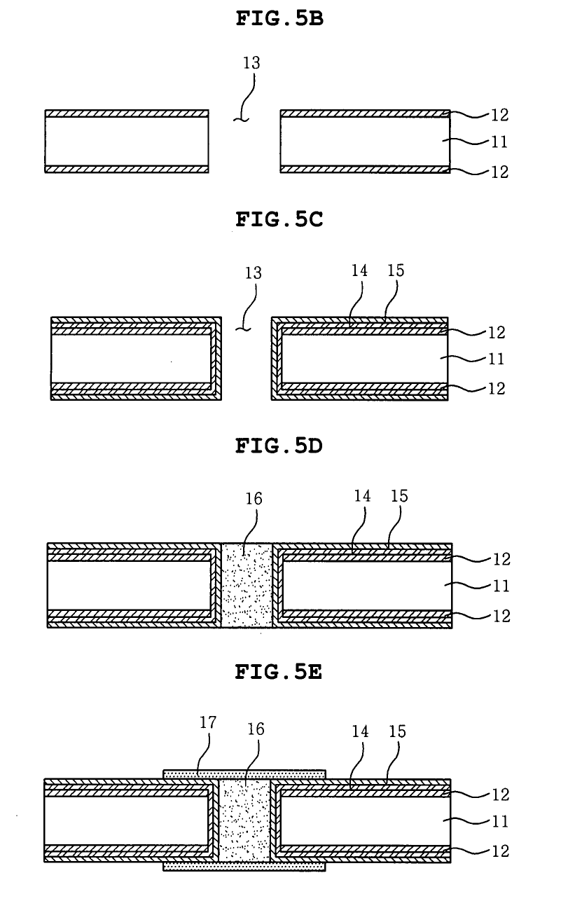

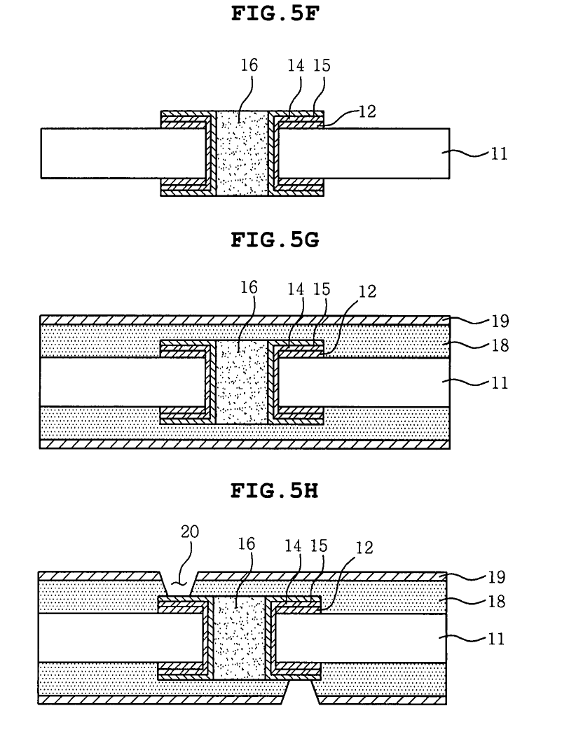

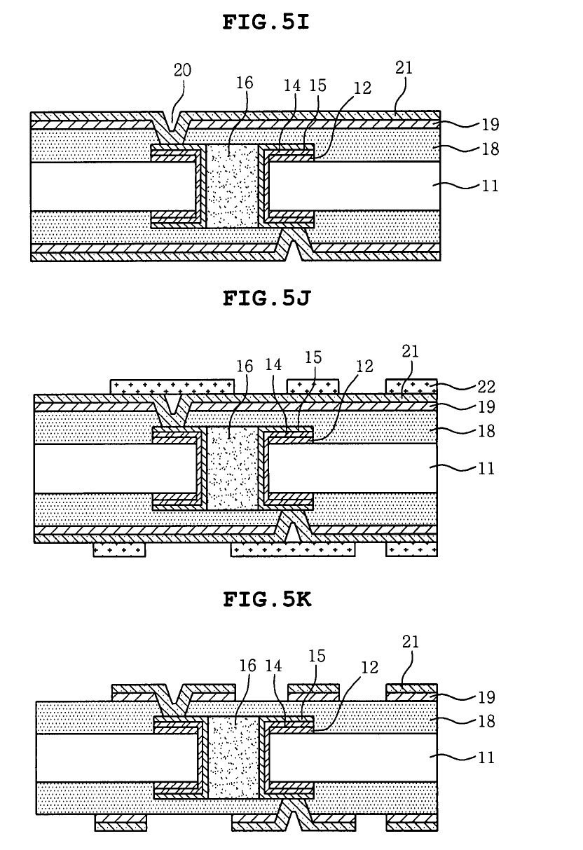

FIGS. 3 and 4 are optical microscope photos showing the sections of examples of printed circuit boards manufactured according to the above-described processes, and are magnified 500 times.

FIG. 3 shows an actual example of the substrate shown in FIG. 1F. Although the conditions of the process of layering the substrates are not particularly limited, this process may be performed at a temperature ranging from 180° C. to 220° C. and a pressure ranging from 30 to 40 kg/cm². A polyimide substrate having a thickness of 25 μm is used as the high-functional resin substrate, and RPG having a thickness of 40 μm is used as the adhesive insulating layer.

FIG. 4 is a view showing a state in which separate polyimide substrates are layered on the substrates, manufactured according to FIG. 1J, using PPG as adhesive insulating layers.

Although a build-up printed circuit board, constructed as described above, is generally applicable to High-density Interconnection HDI(HDI), an Ultra Thin-Chip Scale Package (UT-CSP), a Ball Grid Array (BGA), or a Flip Chip BGA (FCBGA), the build-up printed circuit board is applicable to all types of products for implementing fine circuits. As described above, the present invention uses a high-functional insulating substrate material. Since the insulating substrate material used has a uniform thickness, the substrate material has improved impedance uniformity and excellent insulation properties, compared to an epoxy insulating substrate material, such as BT, which is the existing build-up insulating substrate material. Further, the internal circuit patterns are buried in the insulating layer, thereby reducing the total thickness of the substrate. Furthermore, the circuit patterns are formed on layers outside the substrates using a semiadditive method, the walls of the via hole and the interlayer through hole are simultaneously metal-plated, and thus it is possible to manufacture a thin printed circuit board that has a small thickness and fine patterns.

The advantages of the present invention will be described as follows:

(1) Application of high-functional insulating material to high-density printed circuit board through ion-beam process

For example, since a high-functional insulating material, such as PI, LCP, or PTFE, having a permittivity ranging from 1.5 to 4.0, has low permittivity and low dielectric loss, compared to a BT insulating material used as the main material of a package substrate, the high-functional insulating material may be used for a high-frequency substrate.

In the existing wet-processing method, the adhesiveness between a high-functional insulating material, such as PI, LCP, or PTFE, and a conductive layer is not sufficiently ensured, so that the high-functional insulating material is limitedly used as an interlayer insulating material. However, the adhesiveness between the insulating material and the conductive layer can be improved through ion-beam surface treatment, which ensures high reliability, so that the high-functional insulating material can be applied to such a package substrate.

(2) Structure of ultra thin substrate

Since a circuit formed on one surface of each of the substrates is buried in an adhesive insulating layer and a separate circuit is formed on the remaining surface of the substrate, an ultra thin substrate can be implemented.

(3) Improvement of impedance uniformity due to uniform thickness of insulating layer

Since the existing build-up substrate materials have nonuniform thicknesses, the impedances thereof are not uniform. However, hardened materials are used in the present invention, so that layers have a uniform thickness and the total thickness thereof is reduced, thereby obtaining excellent impedance uniformity.

(4) Implementation of fine circuits having a size equal to or less than 25/25 μm using semiadditive method

Since a semiadditive method is applied to all processes, it is possible to form a fine circuit having 50 or fewer pitches, wherein 50 pitches is the limit on the number of pitches of a fine pattern formed using the existing subtractive method and the existing semiadditive method using a thin copper foil.

(5) Reduction of deformation occurring when forming circuit on one surface of substrate, and improvement of layer-to-layer registration

When circuits are formed on both surfaces of a film-type substrate made of a material such as PI, deformation attributable to heat may occur. However, if a circuit is formed on one surface of the substrate, a process of forming the circuit may be performed with a remaining surface of the substrate attached to a cooling system, thereby being capable of reducing deformation attributable to heat, therefore layer-to-layer registration is improved.

Although the preferred embodiments of the present invention have been disclosed for illustrative purposes, the printed circuit board and the method of manufacturing the printed circuit board according to the present invention are not limited thereto. Those skilled in the art will appreciate that various modifications, additions and substitutions are possible, without departing from the scope and spirit of the invention as disclosed in the accompanying claims.

What is claimed is:

1. A printed circuit board, comprising:
(A) a first resin substrate having a first circuit pattern on one surface thereof;
(B) a second resin substrate having a second circuit pattern on one surface thereof;
(C) an insulating layer interposed between the first resin substrate and the second resin substrate, with the first circuit pattern and the second circuit pattern being positioned inside the first and second resin substrates;
(D) one or more blind via holes and one or more through holes formed in the first resin substrate, the second resin substrate, and the insulating layer;
(E) a third circuit pattern formed on a remaining surface of the first resin substrate, and a fourth circuit pattern formed on a remaining surface of the second resin substrate; and
(F) a metal layer formed on a wall of the through hole;
wherein the first and second resin substrates have a permittivity ranging from 1.5 to 4.0; and
wherein the first to fourth circuit patterns are each formed of a metal seed layer formed through ion-beam surface treatment and vapor deposition, and a metal electrolytic plating layer formed through electroplating.

2. The printed circuit board as set forth in claim 1, wherein resins of the first and second resin substrates are selected from the group consisting of PolyTetraFluoroEthylene (PTFE), PolyImide (PI), Liquid Crystal Polymer (LCP), and combinations thereof.

3. The printed circuit board as set forth in claim 1, wherein the insulating layer is made of material selected from the group consisting of thermoplastic resin, thermosetting resin, reinforced thermoplastic resin, reinforced thermosetting resin, and combinations thereof.

4. A method of manufacturing a printed circuit board, comprising:
(A) providing a pair of resin substrates having a permittivity ranging from 1.5 to 4.0;
(B) processing one surface of each of the resin substrates using an ion-beam;
(C) forming a metal seed layer on each of the pair of resin substrates, the surfaces of which are processed using a vapor deposition process;
(D) forming a metal pattern plating layer on the metal seed layer using an electroplating process;
(E) removing the metal seed layer disposed on portions where the metal pattern plating layer is not formed, and forming a circuit pattern;
(F) disposing an insulating layer between the pair of resin substrates, on one surface of each of which the circuit pattern is formed, with the circuit patterns being disposed inside the pair of resin substrates;
(G) forming one or more blind via holes and a through hole in the layered resin substrates; and
(H) processing the surfaces of the resin substrates, in which the blind via holes and the through hole are formed, using an ion beam, and repeating the steps of (C) to (E).

5. The method of manufacturing a printed circuit board as set forth in claim 4, wherein the resin substrates are C-stage films.

6. The method of manufacturing a printed circuit board as set forth in claim 4, wherein the processing of the surfaces of the resin substrates using an ion beam is performed in a state in which an inactive gas selected from the group consisting of Ar, O₂, N₂, Xe, CF₄, H₂, Ne, Kr and combinations thereof exists.

7. The method of manufacturing a printed circuit board as set forth in claim 4, wherein the vapor deposition process is selected from the group consisting of a sputter process, a thermal evaporation process, an e-beam process, and combinations thereof.

8. The method of manufacturing a printed circuit board as set forth in claim 4, wherein the resins of the resin substrates are selected from the group consisting of polytetrafluoroethylene, polyimide, liquid crystal polymer, and combinations thereof.

9. The method of manufacturing a printed circuit board as set forth in claim 4, wherein the insulating layer is made of material selected from the group consisting of thermoplastic resin, thermosetting resin, reinforced thermoplastic resin, reinforced thermosetting resin, and combinations thereof.

10. A printed circuit board, comprising:
(A) a first resin substrate including a first circuit pattern having a first land on one surface thereof;
(B) a second resin substrate including a second circuit pattern having a second land on one surface thereof;
(C) an insulating layer interposed between the first resin substrate and the second resin substrate, with the first circuit pattern and the second circuit pattern being disposed inside the first and second resin substrates;
(D) one or more bumps formed therebetween to electrically connect the first land and the second land;
(E) one or more blind via holes formed in the first resin substrate and the second resin substrate; and
(F) a third circuit pattern formed on a remaining surface of the first resin substrate, and a fourth circuit pattern formed on a remaining surface of the second resin substrate;
wherein the first and second resin substrates have a permittivity ranging from 1.5 to 4.0; and
wherein the first to fourth circuit patterns are each formed of a metal seed layer formed through ion-beam surface treatment and vapor deposition, and a metal electrolytic plating layer formed through electroplating.

11. The printed circuit board as set forth in claim 10, wherein resins of the first and second resin substrates are selected from the group consisting of polytetrafluoroethylene, polyimide, liquid crystal polymer, and combinations thereof.

12. The printed circuit board as set forth in claim 10, wherein the insulating layer is made of material selected from the group consisting of thermoplastic resin, thermosetting resin, reinforced thermoplastic resin, reinforced thermosetting resin, and combinations thereof.

13. A method of manufacturing a printed circuit board, comprising:
(A) providing a resin substrate having a permittivity ranging from 1.5 to 4.0;
(B) processing one surface of the resin substrate using an ion-beam;
(C) forming a metal seed layer on the resin substrate, the surface of which is processed using a vapor deposition process;
(D) forming a metal pattern plating layer on the metal seed layer using an electroplating process;
(E) removing the metal seed layer disposed on portions on which the metal pattern plating layer is not formed, and forming a circuit pattern including a land;
(F) forming one or more cone-shaped bumps on the land;
(G) layering an insulating layer on the resin substrate on which the cone-shaped bumps are formed, with the cone-shaped bumps passing through the insulating layer, so that a part of the bumps are exposed;
(H) preparing a resin substrate including a circuit pattern having a land by repeating the steps of (A) to (E);
(I) layering the resin substrate obtained in the step (H), on the insulating layer obtained in the step (G), through which a part of the cone-shaped bumps are exposed, wherein the bumps are interposed between the lands opposite each other;
(J) forming one or more blind via holes in the layered resin substrates obtained in the step (I); and
(K) processing surfaces of the resin substrates, through which the blind via holes are formed, using an ion beam, and repeating the steps of (C) to (E).

14. The method of manufacturing a printed circuit board as set forth in claim 13, wherein the resin substrates are C-stage films.

15. The method of manufacturing a printed circuit board as set forth in claim 13, wherein the processing of the surfaces of the resin substrates using an ion beam is performed in a state in which an inactive gas selected from the group consisting of Ar, O₂, N₂, Xe, CF₄, H₂, Ne, Kr and combinations thereof exists.

16. The method of manufacturing a printed circuit board as set forth in claim 13, wherein the vapor deposition process is selected from the group consisting of a sputtering process, a thermal evaporation process, an e-beam process, and combinations thereof.

17. The method of manufacturing a printed circuit board as set forth in claim 13, wherein the resins of the resin substrates are selected from the group consisting of polytetrafluoroethylene, polyimide, liquid crystal polymer, and combinations thereof.

18. The method of manufacturing a printed circuit board as set forth in claim 13, wherein the insulating layer is made of material selected from the group consisting of thermoplastic resin, thermosetting resin, reinforced thermoplastic resin, reinforced thermosetting resin, and combinations thereof.
